(19) United States
(12) Patent Application Publication
(10) Pub. No.: US 2007/0245217 A1
(43) Pub. Date: Oct. 18, 2007

(54) Low-density parity check decoding

(75) Inventor: Stefano Valle, Milano (IT)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMicroelectronics S.r.l., Agrate Brianza (IT)

(21) Appl. No.: 11/729,846

(22) Filed: Mar. 28, 2007

Related U.S. Application Data
(60) Provisional application No. 60/787,063, filed on Mar. 28, 2006.

(51) Int. Cl. H03M 13/00

(52) U.S. Cl. 714/758

(57) ABSTRACT

Low Density Parity Check encoded signals propagated over a channel are decoded by iteratively producing messages representative of the a-posteriori probability of output decoded signals as a function of check-to-bit messages produced from bit-to-check messages via check-node update computation. The check-node update computation is performed as a MIN-SUM approximation and the reliability of the output messages from the check-node update computation is determined by the least reliable incoming message M(i). The decoding includes: identifying the smallest and second smallest modulus of bit-to-check messages, the signs of output messages and the position of a least reliable incoming message, and producing an updated version of the messages representative of the a-posteriori probability as a function of the smallest or the second smallest of i-th check-to-bit messages, the signs of said output messages and the position of said least reliable incoming message.

### BACKGROUND OF THE INVENTION

1. Field of the Invention

This disclosure relates to error correction codes for use in digital communication systems and digital data storage systems, and specifically to Low-Density Parity Check (LDPC) coding and decoding.

2. Description of the Related Art

As schematically shown in FIG. 1 of the annexed views, a digital communication system 1 typically consists of a transmitter TX 2 producing signals representative of data, a communication channel CH over which the signals are propagated, and a receiver RX 3 for receiving the signals after propagation over the channel CH. A digital data storage system can be seen as a communication system where the write apparatus is the transmitter, the storage media is the communication channel, and the read apparatus is the receiver. Not unlike a communication channel, a storage media channel, e.g., the Read/Write Channel of a Hard Disk Drive, suffers from errors.

A transmitter TX 2 consists of a source 10 of digital data, a channel coding apparatus (encoder 12) to encode data in order to produce output data 14 that are more robust against errors due to the communication channel, and a modulator 16 to “translate” the encoded bits 14 into a signal suitable to be transmitted over the channel CH. The receiver RX 3 consists of a demodulator 18 that translates the received signals into bit likelihood values. Bit likelihood values are then processed by a decoder 20 that retrieves the source bits as the decoded data 22.

A channel coding scheme consists of an encoder part 12 on the transmitter side and a decoder part 20 included in the receiver part. For bi-directional links, the encoder 12 and the decoder 20 may be instantiated on both sides to support transmitter and receiver role. Starting from the information bits provided by the source 10, the encoder 12 derives—for example, on the basis of the error correction code—the output data bit stream 14. The decoder 20 aims at retrieving the information bits from the encoded bit stream produced by the transmitter TX, which may be corrupted as a result of being propagated over the channel and due to the characteristics of the transmission and reception apparatus being non-ideal.

Low Density Parity Check Coding (LDPCC) are block codes defined by their parity check matrix, which is sparse and random. The decoding algorithm is iterative and is based on the message passing (MP) on a bipartite graph (namely also Sum-Product-Algorithm (SPA)). These codes and the corresponding decoding algorithm were proposed in Gallager R. G.: Low-Density Parity-Check Codes, IRE Trans. Information Theory: January 1962, pp. 22-28.

Despite their good properties, these codes and the corresponding decoding algorithm were neglected for many years with only very few exceptions. The codes were “re-discovered” in 1995 by MacKay in D. J. C. MacKay and R. M. Neal, “Good codes based on very sparse matrices,” in Cryptography and Coding. 5^{th} IMA Conf., Colin Boyd, Ed., number 1025 in lecture notes in computer science. Berlin, Germany: Springer, 1995, pp. 100-11. Interest soon grew up also in combination with the great success of Turbo Codes (see e.g., C. Berrou, A. Glavieux, and P. Thitimajshima, “Near Shannon limit error-correcting coding and decoding: Turbo-codes,” in Proc. IEEE Intl. Conf. Commun., (Geneva), pp. 1064-70, May 1993) whose iterative decoding algorithm is very similar.

In fact, Low Density Parity Check Coding (LDPCC) is an Error Correction Code (ECC) technique that is being increasingly regarded as a valid alternative to Turbo Codes. LDPC codes have been incorporated into the specifications of several real systems, and the LDPCC decoder may turn out to constitute a significant portion of the corresponding digital transceiver. The bulk of an LDPC decoder is comprised of memories and check-node processing unit(s).

A typical parity check matrix H (m×n) for an error correcting code (ECC) may take the form

$$H = [ \begin{matrix}0 & 0 & 1 & 0 & 0 & 1 & 1 & 1 & 0 & 0 & 0 & 0 \\ 1 & 1 & 0 & 0 & 1 & 0 & 0 & 0 & 0 & 0 & 0 & 1 \\ 0 & 0 & 0 & 1 & 0 & 0 & 0 & 0 & 1 & 1 & 1 & 0 \\ 0 & 1 & 0 & 0 & 0 & 1 & 1 & 0 & 0 & 1 & 0 & 0 \\ 1 & 0 & 1 & 0 & 0 & 0 & 0 & 1 & 0 & 0 & 1 & 0 \\ 0 & 0 & 0 & 1 & 1 & 0 & 0 & 0 & 1 & 0 & 0 & 1 \\ 1 & 0 & 0 & 1 & 1 & 0 & 1 & 0 & 0 & 0 & 0 & 0 \\ 0 & 0 & 0 & 0 & 0 & 1 & 0 & 1 & 0 & 0 & 1 & 1 \\ 0 & 1 & 1 & 0 & 0 & 0 & 0 & 0 & 1 & 1 & 0 & 0\end{matrix} ] \qquad Eq 1$$

where m is the number of rows and n is the number of columns; the code rate of a code defined by the parity check matrix H is given by R=k/n=(n−m)/n. Each code-word c of length (n×1) satisfies the equation:

Hc=0 Eq 2

in modulo-2 arithmetic.

LDPCC are usually defined by the parity check matrix H for which a unique correspondence between an information-word u and a code-word c is not defined. In order to establish such correspondence a generator matrix G (k×n) may be defined for which:

G^{T}u=c Eq 3

Usually, one prefers a systematic code; in this case the generator matrix is in the form:

$${G}^{T} = [ \begin{matrix}{I}_{k} \\ P\end{matrix} ] \qquad Eq 4$$

The matrix P may be obtained by applying the Gaussian elimination to the parity check matrix H (see, for instance MacKay D. J. C., Good Error-Correcting Codes Based on Very Sparse Matrices, IEEE Trans. Inform. Theory, vol. 45, n. 1, pp. 399-431, March 1999) in order to obtain an equivalent parity check matrix in the form:

H=[P\Iₘ] Eq 5

Parity check matrixes are sparse in the sense that the fraction of ones grows linearly with code-word length n (instead of quadratically); thus sparseness makes the decoding of large block (n>10000) still feasible.

An LDPC code can be represented in terms of a bipartite (Tanner) graph as shown in FIG. 2. The variable or bit nodes (circles) correspond to components of the codeword, and the check nodes (squares) correspond to the set of parity-check constraints satisfied by the codewords of the code. Bit nodes are connected through edges to the check nodes that they participate in.

The degree of a variable node is the number of check equations it participates in. Similarly, the degree of a check node is the number of variable nodes which take part in that particular check. If all variable (check) nodes have the same degree, then the LDPC code is regular. For regular codes, one can define the following parameters:
t: number of ones per column (degree of a variable node);
r: number of ones per row (degree of a check node).

A regular LDPCC presents the same number of ones per column (t) and the same of number of ones per row ®. The relationship between these parameters and those previously defined is:

$$R = \frac{k}{n} = 1 - \frac{m}{n} = 1 - \frac{t}{r} \qquad Eq 6$$

where R is the code rate.

If the degrees are different, then the code is irregular. The irregular codes may be characterized using two polynomials called node- and check-degree profiles, respectively. The two polynomials (η, ρ) represent the degree distribution of the code.

As described, e.g., in T. J. Richardson, M. A. Shokrollahi and R. L. Urbanke, “Design of Capacity-Approaching Irregular Low-Density Parity-Check Codes,” IEEE Transactions On Information Theory, vol. 47, No. 2, February 2001 pp. 619-637, an ensemble of codes of length n can be characterized by the degree distribution:

$$η ( x ) = {\sum }_{i = 1}^{{d}_{v}} {η}_{i} {x}^{i - 1} , ρ ( x ) = {\sum }_{i = 1}^{{d}_{r}} {ρ}_{i} {x}^{i - 1} \qquad Eq 7$$

where ηᵢ and ρᵢ represent the fractions of edges that are connected to bit nodes of degree i and check nodes of degree i, respectively. The number of variable nodes of degree i is given by:

$$n \frac{\frac{{η}_{i}}{i}}{{\int }_{0}^{1} η ( x ) d x} \qquad Eq 8$$

Similarly, the number of check nodes of degree i is given by:

$$m \frac{\frac{{ρ}_{i}}{i}}{{\int }_{0}^{1} ρ ( x ) d x} \qquad Eq 9$$

The total number of edges is then given by:

$$Edges = n \frac{1}{{\int }_{0}^{1} η ( x ) d x} = m \frac{1}{{\int }_{0}^{1} ρ ( x ) d x} \qquad Eq 10$$

and corresponding rate of the code is:

$$R = \frac{{\sum }_{i} \frac{{ρ}_{i}}{i}}{{\sum }_{j} \frac{{η}_{j}}{j}} = 1 - \frac{{\int }_{0}^{1} ρ ( x ) d x}{{\int }_{0}^{1} η ( x ) d x} \qquad Eq 11$$

Iterative LDPCC decoders represent a challenging design issue: as indicated, they often represent a major portion of the corresponding digital transceiver.

The complexity issue can be tackled with on different, and often complementary, sides. For instance, check-node processing typically represents the part of the decoder that is most computationally intensive. A possible simplification approach is thus conceptually similar to that adopted for approximating the Log-MAP operator in MAP decoders of Convolutional and Turbo Codes (see, for instance, Viterbi A. J.: An intuitive justification and a simplified implementation of the MAP decoder for convolutional codes: IEEE J. Sel. Areas Commun. February 1998, vol. 16, pp. 269-264). These sophisticated approximations of the basic algorithm originally proposed by Gallager do not lead to performance degradation in the context of a fixed-point implementation. Design trade-off may however lead to give the preference to simplified implementations at the cost of some performance degradation. Exemplary of such an approach is the so-called MIN-SUM (MS) approximation; some effective MS implementations are discussed in Chen, J.; Dholakia, A.; Eleftheriou, E.; Fossorier, M. P. C.; Hu, X.-Y.: Reduced-Complexity Decoding of LDPC Codes, IEEE Trans. on Comm., Vol. 53, N. 8, August 2005 pp. 1288-1299.

LDPC decoder complexity also derives from the large memory requirements. Memory represents the bulk of serial decoders that instantiate a single check-node processor. In high-speed parallel implementations, memory may still represent a significant fraction of the decoder. Moreover, memory accesses are generally complicated by clashes, so that sophisticated memory-paging strategies may be necessary.

As indicated in Boutillon E.; Castura J.; Kschischang F. R.: Decoder-First Code Design: Proceedings of the 2^{nd} Intern. Symp. on Turbo Codes, pp. 459-462, LDPCC design should consider memory conflicts to avoid problems during the decoder design. This point is discussed to some extent in Mansour M. M. and Shanbhag N. R.: High-Throughput LDPC Decoders, IEEE Trans. On VLSI Systems, vol. 11, No. 6, December 2003, pp. 976-996 (including an interesting presentation of the most practical approaches to reduce memory requirements and to structure the code in order to simplify conflicts in memory addressing), and in Zhong H.; Zhang T.: Block-LDPC: A Practical LDPC Coding System Design Approach, IEEE Trans. On Circuits and Systems-I: Regular Papers, Vol. 52, No. 4, April 2005 as well as in the references cited therein). Also, Prabhakar, A.; Narayanan, K.: A Memory Efficient Serial LDPC Decoder Architecture, IEEE Intern Conf. on Acoustics, Speech, and Signal Processing, 2005. Proceedings. (ICASSP '05), Volume 5, Mar. 18-23, 2005, pp. 41-44 demonstrate how the MS operator can be conveniently exploited to reduce the memory requirements of a serial decoder.

The convergence speed of the decoding algorithm is another factor to investigate in the quest for low-complexity decoders. Significant improvements in convergence speed have been observed as a result of some scheduling variations: Mansour et al. (already cited), and Hocevar D. E.: A reduced complexity decoder architecture via layered decoding of LDPC Codes, IEEE Workshop on Signal Processing Systems (SIPS), October 2004, pp. 107-112, as well as the references cited therein provide a complete presentation of these concepts. The scheduling algorithm proposed in Hocevar, namely layered decoding, will be further considered in the following.

The Sum-Product-Algorithm (SPA) was originally introduced by Gallager (cited previously) in the probability and Log-Likelihood Ratios (LLR) domains. The LLR domain version is generally preferred in digital implementations. The LLR is defined as:

$$λ = ln [ \frac{p ( 1 )}{p ( 0 )} ] \qquad Eq 12$$

where p(0) and p(1) are the bit likelihoods and p(0)=1-p(1).

A number of entities are involved in defining the SPA, namely:
Rᵢⱼ; the check-to-bit message from check-node i to bit-node j;
Qⱼᵢ: the bit-to-check message from bit-node j to check-node i;

C(j): the index set of check-nodes involving bit-node j;

V(i): the index set of bit-nodes involved in check-node i.

A single iteration comprises two phases, wherein phase I involves updating all check-nodes by sending extrinsic messages to bit-nodes and phase 2 involves updating all bit-nodes by sending extrinsic messages to check-nodes. An initialization phase sets Qⱼᵢ equal to λⱼ for all i and j. The basic principle underlying the SPA is shown below, where the first inner loop and the second inner loop represent the reiterated phase 1 and phase 2, and Nite is the number of iterations. The algorithm terminates with the computation of the A-Posteriori Probability Λⱼ.

Qⱼᵢ = λⱼ ∀i, j
for k = 1:Nᵢₜₑ

for i = 1:nc

for j ∈ V(i)

$\begin{matrix}{R}_{ij} = {Φ}^{- 1} \{ ( {\sum }_{m ∈ V ( i )} Φ ( \vert {Q}_{mi} \vert ) ) - Φ ( \vert {Q}_{ji} \vert ) \} • \\ ( sign ( {Q}_{ji} ) • {\prod }_{m ∈ V ( i )} sign ( {Q}_{mi} ) )\end{matrix}$

for j = 1:nv

for i ∈ C(j)

${Q}_{ji} = {λ}_{j} + ( {\sum }_{i ∈ C ( j )} {R}_{ij} ) - {R}_{ij}$

${Λ}_{j} = {λ}_{j} + ( {\sum }_{i ∈ C ( j )} {R}_{ij} ) ∀ j$

The function Φ is defined as:

$$Φ ( x ) = {Φ}^{- 1} ( x ) = - log ( tanh ( \frac{x}{2} ) ) \qquad Eq 13$$

The memory to store the messages Rᵢⱼ and Qⱼᵢ is MSPA=2*E*N_{b}, where E is the number of edges in the Tanner graph and N_{b} is the number of bits to represent each message.

In Mansour et al. (already cited) the authors observed that the extrinsic messages Qⱼᵢ be computed “on the fly”, while the Λⱼ's are the only messages to be stored.

A possible resulting algorithm merges check and bit-node updates (Merged SPA, M-SPA), and is illustrated below. There Q and A exchange theirs roles in a ping-pong fashion each iteration; \tilde{Q}ᵢⱼ are computed on the fly and do not need to be stored. The memory to store the messages Rᵢⱼ, Qⱼᵢ and Λⱼ is MM-SPA=(E+2*n)*N_{b}, where n is the codeword length.

Qⱼ = λⱼ ∀ j
for k = 1:Nᵢₜₑ

Λⱼ = λⱼ ∀ j
for i = 1:nc

for j ∈ V(i)

${\tilde{Q}}_{ji} = {Q}_{j} - {R}_{ij}$
${R}_{ij} = {Φ}^{- 1} \{ ( {\sum }_{m ∈ V ( i )} Φ ( \vert {\tilde{Q}}_{mi} \vert ) ) - Φ ( \vert {\tilde{Q}}_{ji} \vert ) \} • \\ ( sign ( {\tilde{Q}}_{ji} ) • {\prod }_{m ∈ V ( i )} sign ( {\tilde{Q}}_{mi} ) )$
Λⱼ = Λⱼ + Rᵢⱼ

The layered schedule considered for this algorithm was introduced in Mansour et al. (already cited) and formulated in a more compact way in Hocevar (already cited—see also US-A-2004/194007).

The core of the algorithm (Layered Schedule SPA, L-SPA) comes from the observation that, after a check-node update, newer extrinsic information is ready to be used by the check-nodes that follow in the decoding schedule. As a consequence, a bit-to-check-node message is updated as soon as a check-node update is performed, for those bits that are involved. In this way, faster convergence of the iterative decoding is achieved and it is demonstrated that half the iterations are sufficient to achieve the same error rate of the conventional SPA.

The algorithm is a very simple modification of the M-SPA and it is illustrated below.

Λⱼ = λⱼ ∀ j
for k = 1:Nᵢₜₑ

for i = 1:nc

for j ∈ V(i)

${\tilde{Q}}_{ji} = {Λ}_{j} - {R}_{ij}$
${R}_{ij} = {Φ}^{- 1} \{ ( {\sum }_{m ∈ V ( i )} Φ ( \vert {\tilde{Q}}_{ji} \vert ) ) - Φ ( \vert {\tilde{Q}}_{ji} \vert ) \} • \\ ( sign ( {\tilde{Q}}_{ji} ) • {\prod }_{m ∈ V ( i )} sign ( {\tilde{Q}}_{ji} ) )$
${Λ}_{j} = {\tilde{Q}}_{ji} + {R}_{ij}$

In this case, memory requirements are further reduced, since only the messages Rᵢⱼ and Λⱼ are to be stored. As a result, ML-SPA=(E+n)*N_{b}.

This principle is generally applicable to every LDPCC class; however, real advantages come when sets of non-overlapping check-equations are present. In this case it is possible to run simultaneously the check-node and bit-node update over all the non-overlapping parity checks, and thus the exploitation of the algorithm in a high-speed decoder becomes feasible. Structured LDPCC, built with sub-blocks that consist of a permutation of the identity matrix, naturally exhibits this feature (see again Mansour et al., already cited). The most appreciated permutations are simple right (or left) cyclic shifts of each row (see, e.g., Tanner R. M.; Sridhara D.; Sridharan A.; Fuja T. E.; Costello D. J.: LDPC Block and Convolutional Codes Based on Circulant Matrices: IEEE Trans. Inform. Theory, Vol. 50, No. 12, December 2004).

This approach simplifies memory management. For example, structured LDPC codes as provided for in the IEEE 802.11n and IEEE 802.16e standards are based on submatrixes blocks (or subblocks) that can be zeros or cyclically shifted versions of the identity matrix. In this way, a parity check is built with ncb rows of subblocks; each row has nvb subblocks. A group of consecutive rows belonging to the same subblock row is often named supercode.

A prototype example of size 8×24 for the IEEE 802.16e standard is given in Table 1 below; the code rate is ⅔ (54×8 parity e 54×16 info bits, thus leading to a 24×54 codeword). This code is designed for subblock size 54. The integer number entries represent the right cyclic shift to be applied to the 54×54 identity matrix; ‘−’ represent the 54×54 null-matrix.

The corresponding matrix is plotted in FIG. 3 where dots represent the positions of non-null elements of the parity check matrix. It is worth noting that the encoding complexity issue, not considered in this context, represents the other driving factor that determines the code structure choice (see, e.g., Richardson T. and Urbanke R.: Efficient encoding of low-density parity-check codes. IEEE Trans. Inform. Theory, vol. 47, February 2001, pp 638-656).

TABLE 1

| | | | | | | | | | | | | | | | | | | | | | | | |
|---|---|---|---|---|---|---|---|---|---|---|---|---|---|---|---|---|---|---|---|---|---|---|---|
| 39 | 31 | 22 | 43 | — | 40 | 4 | — | 11 | — | — | 50 | — | — | — | 6 | 1 | 0 | — | — | — | — | — | — |
| 25 | 52 | 41 | 2 | 6 | — | 14 | — | 34 | — | — | — | 24 | — | 37 | — | — | 0 | 0 | — | — | — | — | — |
| 43 | 31 | 29 | 0 | 21 | — | 28 | — | — | 2 | — | — | 7 | — | 17 | — | — | — | 0 | 0 | — | — | — | — |
| 20 | 33 | 48 | — | 4 | 13 | — | 26 | — | — | 22 | — | — | 46 | 42 | — | — | — | — | 0 | 0 | — | — | — |
| 45 | 7 | 18 | 51 | 12 | 25 | — | — | — | 50 | — | — | 5 | — | — | — | 0 | — | — | — | 0 | 0 | — | — |
| 35 | 40 | 32 | 16 | 5 | — | — | 18 | — | — | 43 | 51 | — | 32 | — | — | — | — | — | — | — | 0 | 0 | — |
| 9 | 24 | 13 | 22 | 28 | — | — | 37 | — | — | 25 | — | — | 52 | — | 13 | — | — | — | — | — | — | 0 | 0 |
| 32 | 22 | 4 | 21 | 16 | — | — | — | 27 | 28 | — | 38 | — | — | — | 8 | 1 | — | — | — | — | — | — | 0 |

Other documents providing background for this disclosure include:
JP A 2004/147318;
Wu Z. and Burd G.: “Equation Based LDPC Decoder for Intersymbol Interference Channels”, IEEE International Conference on Acoustics, Speech, and Signal Processing (ICASSP)—ICASSP 2005 Proceedings—vol. 5, pages V-757 to V-760; and
Novichkov V.; Jin H.; T. Richardson: Programmable vector processor architecture for irregular LDPC codes: Cont. on Inform. Systems and Sciences, (Princeton, N.J.), March 2004, pp. 1141-1146 and WO-A-02/103631, both relating to vectorized decoders explicitly dedicated to structured LDPCC.

### BRIEF SUMMARY OF THE INVENTION

An object of an embodiment of the invention is to introduce an improved LDPC decoding algorithm.

An object of an embodiment of the invention is to provide memory efficient approach to store check-to-bit messages in LDPC decoding.

An object of an embodiment of the invention is the joint adoption of MIN-SUM approximation and layered decoding in LDPC decoding.

An object of an embodiment of the invention is a possible architecture for structured LDPCC with reduced memory and simplified message routing.

These and other objects may be achieved by means of embodiments of a method having the features set forth in the claims. This disclosure also relates to embodiments of corresponding decoder systems and corresponding computer program products, loadable in the memory of at least one computer and including software code portions for performing the steps of the methods when the product is run on a computer. As used herein, reference to such a computer program product is intended to be equivalent to reference to a computer-readable medium containing instructions for controlling a computer system to coordinate the performance of a method. Reference to “at least one computer” is evidently intended to highlight the possibility for embodiments of the present invention to be implemented in a distributed/modular fashion.

The claims are an integral part of the disclosure provided herein.

An embodiment of the invention exhibits performance levels comparable with the SPA, while memory requirements are about 70% less.

In an embodiment, the present invention provides a new LDPCC decoder which, compared to the conventional Sum-Product Algorithm (SPA) in the LLR domain, adopts the MIN-SUM approximation (possibly enhanced with Normalization or similar techniques); preferably, the check-node is implemented as a searcher of first and second minimum together with the position of the first minimum.

In an embodiment, the MIN-SUM approximation makes it possible to achieve a significant reduction of memory required to store the check-to-bit messages exchanged during the iterative decoding process. An alternative schedule of the SPA algorithms doubles the convergence of the iterative process and jointly reduces the amount of bit-to-check messages to be stored. In an embodiment, the resulting decoding algorithm requires a smaller amount of memory when compared to the commonly used approach (˜75% less is achievable) with comparable performance. Moreover, an embodiment provides a potential simplification of some memory-related design issues that one incurs during the design of high-speed LDPCC decoders.

Embodiments of the invention are particularly suitable for use in those systems that adopt short LDPCC (few hundreds of bits) and/or LDPCC with high coding rate (>˜0.75). Ultra-WideBand (UWB) systems based on an approach similar to Orthogonal Frequency Division Multiplex (OFDM), such as MultiBand-OFDM (MBOA) can benefit from the adoption of LDPCC to improve performance and range. Short LDPCC (see, e.g., in Hsuan-Yu Liu, Chien-Ching Lin, Yu-Wei Lin, Ching-Che Chung, Kai-Li Lin, Wei-Che Chang, Lin-Hung Chen, Hsie-Chia Chang, Chen-Yi Lee, “A 480 Mb/s LDPC-COFDM-Based UWB Baseband Transceiver,”, 2005, Proc. Of Intern. Solid-State Circuits Conf —ISSCC. 2005) may be considered in that respect.

Another interesting field of possible application of embodiments is the Read/Write channel of Hard Disk Drives (see, e.g., Dholakia, A.; Eleftheriou, E.; Mittelholzer, T.; Fossorier, M. P. C., “Capacity-approaching codes: can they be applied to the magnetic recording channel?”, IEEE Comm. Mag, Vol. 42, N. 2, February 2004 Page(s): 122-130). In one embodiment, a method of decoding Low Density Parity Check (LDPC) encoded signals propagated over a channel by iteratively producing messages Λⱼ representative of the a-posteriori probability of output decoded signals as a function of check-to-bit messages Rᵢⱼ produced from bit-to-check messages Qⱼᵢ via check-node update computation, wherein said check-node update computation is performed as a MIN-SUM approximation and the reliability of the output messages from said check-node update computation is determined by the least or second least reliable incoming message, the method including the steps of: generating bit-to-check messages Qⱼᵢ for parity check (i) from the last version of Λⱼ and past check-to-bit messages represented by Rᵢ¹, Rᵢ², Sᵢⱼ and M(i); identifying the smallest modulus Rᵢ¹ and the second smallest Rᵢ² modulus of said bit-to-check messages Qⱼᵢ, the signs Sᵢⱼ of said output messages and the position M(i) of said least reliable incoming message Qⱼᵢ; and producing an updated version of said messages Λⱼ representative of the a-posteriori probability of output decoded signals as a function of said smallest Rᵢ¹ or the second smallest Rᵢ² of i-th check-to-bit messages, the signs Sₘⱼ of said output messages and the position of said least reliable incoming message M(i), as soon as available out of the check-node update block. In one embodiment, the method includes the step of multiplying the output messages from said check-node update by a scaling factor α to compensate for the effects of MIN-SUM approximation applied in the computation of said reliability. In one embodiment, the method includes the step of running in parallel a plurality of check-node update computations and the step of arranging in parallel to be read simultaneously all the messages related to said plurality of check-node update computations run in parallel. In one embodiment, the method includes the step of implementing said check-node update computations as a search of: a first and a second minimum for said smallest Rᵢ¹ and the second smallest Rᵢ² of said bit-to-check messages, respectively, and the position of said first minimum as the position of said least reliable incoming message M(i).

In one embodiment, a decoder for decoding Low Density Parity Check (LDPC) encoded signals propagated over a channel, wherein said decoding produces messages Λⱼ representative of the a-posteriori probability of output decoded signals as a function of check-to-bit messages Rᵢⱼ produced from bit-to-check messages Qⱼᵢ via check-node update computation, the decoder including computing circuitry to perform said check-node update computation as a MIN-SUM approximation wherein the reliability of the output messages from said check-node update computation is determined by the least or second least reliable of the incoming message Qⱼᵢ, said computing circuitry including check node processor circuitry to identify the smallest Rᵢ¹ and the second smallest Rᵢ² of said check-to-bit messages, the signs Sₘᵢ of said output messages and the position of said least reliable incoming message M(i), and producing said messages Λⱼ representative of the a-posteriori probability of output decoded signals as a function of said smallest Rᵢ¹ and the second smallest modulus Rᵢ² of said check-to-bit messages, the signs Sₘᵢ of said output messages and the position of said least reliable incoming message M(i). In one embodiment, the computing circuitry includes circuitry for multiplying the output messages from said check-node update by a scaling factor α to compensate for the effects of MIN-SUM approximation applied in the computation of said reliability. In one embodiment, the computing circuitry is configured to run in parallel a plurality of check-node update computations arranged in parallel to read simultaneously all the messages related to said plurality of check-node update computations run in parallel. In one embodiment, the computing circuitry includes at least one check-node processor for performing said update computations as a search of: a first and a second minimum for said smallest Rᵢ¹ and the second smallest Rᵢ² of said bit-to-check messages, respectively, and the position M(i) of said first minimum as the position of said least reliable incoming message.

In one embodiment, a decoder for decoding Low Density Parity Check (LDPC) encoded signals propagated over a channel, wherein said decoding produces messages Λⱼ representative of the a-posteriori probability of output decoded signals as a function of check-to-bit messages Rᵢⱼ produced from bit-to-check messages Qⱼᵢ via check-node update computation, the decoder including computing circuitry to perform said check-node update computation as a MIN-SUM approximation wherein the reliability of the output messages from said check-node update computation is determined by the least and second least reliable incoming message, the decoder including memory circuitry for storing the smallest Rᵢ¹ and the second smallest Rᵢ² modulus of said check-to-bit messages, the signs Sₘᵢ of said output messages and the position of said least reliable incoming message M(i) to produce therefrom an updated version of said messages Λⱼ representative of the a-posteriori probability of output decoded signals. In one embodiment, the decoder including at least one modulus memory block for storing said smallest Rᵢ¹ and second smallest Rᵢ² modulus of said check-to-bit messages as well as said position of said least reliable incoming message M(i). In one embodiment, the decoder includes an a-posteriori probability memory block for storing said messages Λⱼ representative of a-posteriori probability, said a-posteriori probability memory block arranged in word locations, each word location adapted for containing the values of a plurality of bit nodes. In one embodiment, the decoder includes at least one shifter element to rotate of given shift values the input messages to said a-posteriori probability memory block and the output messages therefrom. In one embodiment, said at least one shifter element includes a switch-bar. In one embodiment, the decoder includes a sign memory block for storing said signs Sₘᵢ of said check-to-bit messages, said sign memory block arranged in word locations, each word location adapted for containing a plurality of signs belonging to plural messages arranged together to form a memory word. In one embodiment, the decoder includes an a-posteriori probability memory block for storing said messages Λⱼ representative of a-posteriori probability, a sign memory block for storing said signs Sₘᵢ of said check-to-bit messages, computing circuitry for producing said messages Λⱼ representative of the a-posteriori probability of output decoded signals as a function of said smallest modulus Rᵢ¹ and the second smallest Rᵢ² of said check-to-bit messages, the signs Sₘᵢ of said check-to-bit messages and the position of said least reliable incoming message M(i), and demultiplexer circuitry for demultiplexing towards said computing circuitry the outputs from said memory circuitry, said a-posteriori probability memory block and said sign memory block. In one embodiment, said computing circuitry includes at least one check-node processor fed for performing said update computations as a search of: a first and a second minimum for said smallest Rᵢ¹ and the second smallest Rᵢ² of said check-to-bit messages, respectively, and the position of said first minimum as the position of said least reliable incoming message M(i). In one embodiment, the decoder includes multiplexer circuitry for multiplexing the outputs from at least one check-node processor towards said memory circuitry, said a-posteriori probability memory block and said sign memory block.

In one embodiment, a method of decoding Low Density Parity Check (LDPC) encoded signals propagated over a channel comprises: producing messages representative of the a-posteriori probability of output decoded signals; minimum sum (MIN-SUM) approximation and layered decoding.

In one embodiment, a computer program product for decoding Low Density Parity Check (LDPC) encoded signals propagated over a channel by producing messages representative of the a-posteriori probability of output decoded signals, is loadable in the memory of at least one computer and includes software code portions for performing the steps of: iteratively producing messages Λⱼ representative of the a-posteriori probability of output decoded signals as a function of check-to-bit messages Rᵢⱼ produced from bit-to-check messages Qⱼᵢ via check-node update computation, wherein said check-node update computation is performed as a MIN-SUM approximation and the reliability of the output messages from said check-node update computation is determined by the least or second least reliable incoming message, generating bit-to-check messages Qⱼᵢ for parity check (i) from the last version of Λⱼ and past check-to-bit messages represented by Rᵢ¹, Rᵢ², Sᵢⱼ and M(i); identifying the smallest modulus Rᵢ¹ and the second smallest Rᵢ² modulus of said bit-to-check messages Qⱼᵢ, the signs Sᵢⱼ of said output messages and the position M(i) of said least reliable incoming message Qⱼᵢ, and producing an updated version of said messages Λⱼ representative of the a-posteriori probability of output decoded signals as a function of said smallest Rᵢ¹ or the second smallest Rᵢ² of i-th check-to-bit messages, the signs Sₘⱼ of said output messages and the position of said least reliable incoming message M(i), as soon as available out of the check-node update block.

In one embodiment, a decoder for decoding low-density-parity-check encoded signals comprises: a probability memory block for storing a set of check-to-bit messages; a bit-to-check module configured to generate a set of bit-to-check messages from the set of check-to-bit messages; a check node module configured to output a smallest and a second smallest modulus of messages in the set of bit-to-check messages, an identifier of a position associated with the smallest modulus, and a revised set of check-to-bit messages; a modulus memory block configured to store the smallest modulus, the identifier and the second smallest modulus; and a signs memory block configured to store signs of the revised set of check-to-bit messages. In one embodiment, the decoder further comprises a plurality of demultiplexers coupled between the memory blocks and the bit-to-check module, wherein the bit-to-check module comprises a plurality of bit-to-check generators; and a plurality of multiplexers coupled between the check node module and the memory blocks, wherein the check node module comprises a plurality of check node processors. In one embodiment, the decoder further comprises: a first shifter coupled between a multiplexer in the plurality of multiplexers and an input to the probability memory block; and a second shifter coupled between an output of the probability memory block and a demultiplexer in the plurality of demultiplexers.

In one embodiment, a method of decoding low density parity check signals, comprises: storing a set of check-to-bit messages, a smallest modulus, a position associated with the smallest modulus, a second smallest modulus, and a set of signs; generating a set of bit-to-check messages based on the set of check-to-bit messages, the smallest modulus, the position associated with the smallest modulus, the second smallest modulus, and the set of signs; and revising the set of check-to-bit messages based on the set of bit-to-check messages, the smallest modulus, the position associated with the smallest modulus, the second smallest modulus and the set of signs. In one embodiment, generating the set of bit-to-check messages comprises: when the position associated with the smallest modulus corresponds to a position of a message in the set of check-to-bit messages, generating a message in the set of bit-to-check messages based on the second smallest modulus; and when the position associated with the smallest modulus does not correspond to the position of the message in the set of check-to-bit messages, generating the message in the set of bit-to-check messages based on the smallest modulus. In one embodiment, revising the set of check-to-bit messages comprises applying a scaling factor. In one embodiment, the method further comprises: revising the smallest modulus, the position associated with the smallest modulus, the second smallest modulus, and the set of signs.

In one embodiment, a computer-readable memory medium contains instructions that cause a processor to perform a method of decoding low density parity check signals, the method comprising: storing a set of check-to-bit messages, a smallest modulus, a position associated with the smallest modulus, a second smallest modulus, and a set of signs; generating a set of bit-to-check messages based on the set of check-to-bit messages, the smallest modulus, the position associated with the smallest modulus, the second smallest modulus, and the set of signs; and revising the set of check-to-bit messages based on the set of bit-to-check messages, the smallest modulus, the position associated with the smallest modulus, the second smallest modulus and the set of signs. In one embodiment, generating the set of bit-to-check messages comprises: when the position associated with the smallest modulus corresponds to a position of a message in the set of check-to-bit messages, generating a message in the set of bit-to-check messages based on the second smallest modulus; and when the position associated with the smallest modulus does not correspond to the position of the message in the set of check-to-bit messages, generating the message in the set of bit-to-check messages based on the smallest modulus. In one embodiment, revising the set of check-to-bit messages comprises applying a scaling factor. In one embodiment, the method further comprises revising the smallest modulus, the position associated with the smallest modulus, the second smallest modulus, and the set of signs.

### BRIEF DESCRIPTION OF THE SEVERAL VIEWS OF THE DRAWINGS

The invention will now be described, by way of example only, with reference to the enclosed views, wherein:

FIG. 1 is a functional block diagram of a digital communication system.

FIG. 2 is a graphical representation of an LDPC code.

FIG. 3 is a graphical representation of the non-null elements of a parity check matrix.

FIG. 4 is a graphical representative of the parity section of an exemplary code structure adapted for use in an embodiment.

FIG. 5 is a functional block diagram representative of a top-level architecture of a decoder according to an embodiment.

### DETAILED DESCRIPTION OF THE INVENTION

By way of introduction of a detailed description of preferred embodiments of the arrangement described herein invention, some of the theoretical principles underlying such an arrangement will now be briefly discussed by way of direct comparison with the related art described in the foregoing.

As a first point, the MIN-SUM (MS) approximation will be shown to be a straightforward simplification of the check-node computation.

In fact:

$${Φ}^{- 1} ( {\sum }_{i} Φ ( {x}_{i} ) ) ≅ {min}_{i} {x}_{i} \qquad Eq 14$$

The reliability of the messages coming out of a check-node update can be expected to be dominated by the least reliable incoming message. The MS outputs are, in modulus, slightly larger than those output by a non-approximated check-node processor. This results in a significant error rate degradation.

For this reason, Chen et al. (already cited in the foregoing) have proposed to resort to Normalized-MS (N-MS) to partially compensate for these losses: N-MS typically consists of a simple multiplication of the output messages by a scaling factor. The factor can be optimized through simulations or, in a more sophisticated way, with density evolution as disclosed by Chen et al.

This approach recovers most of the performance gap caused by MS and makes MS a valid alternative to a full processing approach. An almost equivalent alternative to the N-MS is the Offset-MIN-SUM (O-MS), again disclosed by Chen et al., that performs slightly worse than N-MS.

A MS decoder does not require knowledge of the noise variance, which is of great interest when the noise variance in unknown or hard to be determined. More sophisticated approximations are able to perform nearly the same as a full precision approach, but generally require a data dependent correction term that makes the check-node processor more complex. This specific issue has been investigated in the art (see, e.g., Zarkeshvari, F. Banihashemi, A. H.: On implementation of min-sum algorithm for decoding low-density parity-check (LDPC) codes: GLOBECOM '02. IEEE Vol. 2, 17-21 November 2002, pp. 1349-1353).

Parallel or partially parallel architectures employ a multiplicity of check-node processors. For this reason any simplification of this computation kernel is of particular interest. When MS is adopted, the same modulus is shared by all outgoing messages from a check-node update processor; its value is equal to the smaller modulus among the incoming messages. The only exception is the outgoing message that corresponds to bit whose incoming massage has the smaller modulus. The modulus of such outgoing message is equal to the second smaller among the incoming messages.

Hence, the minimum check-to-bit information to be stored is much less in comparison with the approaches described so far. For that reason, Normalized MS approximation, with a memory efficient approach, is proposed here in conjunction with the layered decoding (L-SPA) to compensate for the MS performance degradation thanks to the faster convergence given by the scheduling modification. While a more detailed analysis of the storage capability will be provided in the following, with a detailed comparison with the other cases, it will noted that, by adopting the approach described herein, storing (i) two moduli; (ii) the signs of all the outgoing messages; (iii) the position of the least reliable message will suffice. The new approach is capable of outperforming conventional SPA with the same number of iterations, while requiring about 70% less memory. The approach considered here (which may be designated Layered-Normalized-MIN-SUM, i.e., L-N-MS) applies a memory efficient normalized MIN-SUM approach to a layered decoding schedule is schematically represented below.

Λⱼ = λⱼ ∀ j
for k = 1:Nᵢₜₑ

for i = 1:nc

for j ∈ V(i)

if j ≠ M(i)

${\tilde{Q}}_{ji} = {Λ}_{j} - {R}_{i}^{1} {S}_{ij}$

else

${\tilde{Q}}_{ji} = {Λ}_{j} - {R}_{i}^{2} {S}_{ij}$

${R}_{i}^{1} = min \vert {\tilde{Q}}_{ji} \vert \text{/} α$
$M ( i ) = {arg}_{j} min \vert {\tilde{Q}}_{ji} \vert$
${R}_{i}^{2} = {min}_{j \neq M ( i )} \vert {\tilde{Q}}_{ji} \vert \text{/} α$
for j ∈V(i)

${S}_{ij} = ( sign ( {\tilde{Q}}_{ji} ) • {\prod }_{m ∈ V ( i )} sign ( {\tilde{Q}}_{mi} ) )$
if j ≠ M(i)

${Λ}_{j} = {\tilde{Q}}_{ji} + {R}_{i}^{1} {S}_{ij}$

else

${Λ}_{j} = {\tilde{Q}}_{ji} + {R}_{i}^{2} {S}_{ij}$

where Rᵢ¹ and Rᵢ², are the smallest and second smallest check-to-bit message modulus, M(i) is the least reliable bit in equation i, Sₘᵢ are the signs of the outgoing messages and α is the scaling factor of N-MS.

Performance of the L-M-MS proposed herein can be compared with performance achievable with: a layered decoding and pure MS (i.e., without normalization factor) (L-MS); with layered decoding algorithm (L-SPA); and with a conventional SPA.

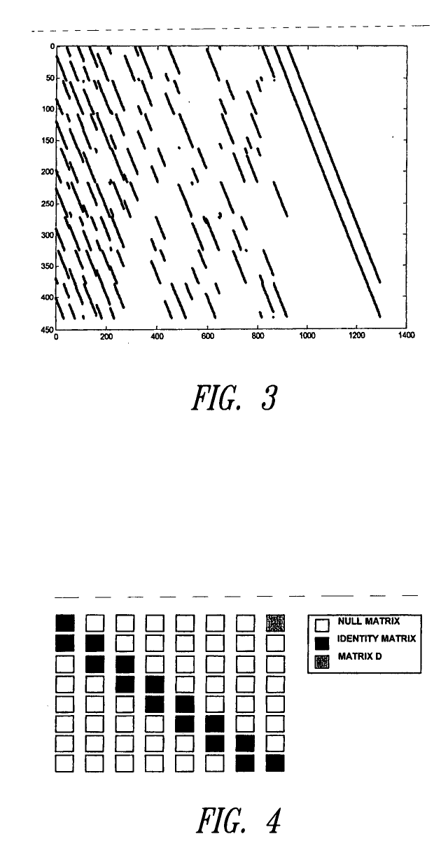

For instance a meaningful comparison can be performed at 25 iterations. As a first example, a structured LDPCC code, designed by the team of Prof. Wesel (University of California Los Angeles) has been used for the comparison. Code is designed with same graph conditioning adopted in Vila Casado A. I.; Weng W.; Wesel R. D.: “Multiple Rate Low-Density Parity-Check Codes with Constant Block Length”, Asilomar Conf. on Signals, Systems and Computers, Pacific Grove, Calif., 2004. The code is 1944 bits long with rate ⅔. It is designed with a combination of 8×24=192 cyclically shifted identity matrices and null matrices of size 81×81. The number of edges is equal to 7613 with maximum variable degree equal to 8 and maximum check degree equal to 13. The parity part is organized as described in FIG. 4.

The upper right matrix D is defined (parity section only) by Eq 15 below for a rate ⅔ code structure.

$$D = [ \begin{matrix}0 & 0 & ⋯ & 0 & 0 & 0 & 0 \\ 1 & 0 & ⋯ & 0 & 0 & 0 & 0 \\ 0 & 1 & ⋯ & 0 & 0 & 0 & 0 \\ 0 & 0 & ⋯ & 0 & 0 & 0 & 0 \\ ⋮ & ⋮ & ⋮ & ⋮ & ⋮ & ⋮ & ⋮ \\ 0 & 0 & ⋯ & 0 & 1 & 0 & 0 \\ 0 & 0 & 0 & 0 & 0 & 1 & 0\end{matrix} ] \qquad Eq 15$$

The results show L-N-MS performs slightly better than conventional SPA, but requires much simpler check-node processing and a dramatically smaller amount of memory. The gap between L-SPA and L-MS is mostly recovered by means of the normalization factor. The normalization factor α has been optimized through simulations focusing on Frame Error Rate—FER equal to 10⁻² with the resulting value equal to 1.35.

As a second example, a high rate structured LDPCC code of similar size has been selected among those proposed in Eleftheriou E.; Ölcer S.: Low density parity-check codes for digital subscriber lines, in Proc., ICC'2002, New York, N.Y., pp. 1752-1757. The code has a linear encoding complexity and supports layered decoding. It is 2209 bits long and it has rate 0.9149. In this case L-N-MS performs even slightly better than the L-SPA. An explanation could be found in the code structure that may have more short cycles compared to the previous example, so that SPA becomes less efficient. The normalization factor α was equal to 1.3.

Fixed-point implementation of N-MS would require a multiplication by a factor with a high accuracy in the quantization level and a significant complexity due to the operator itself. However, it is possible to simplify the normalization procedure at the cost of negligible performance loss.

The normalization can be implemented very efficiently with the following approach:

Q/α1α≅Q−(Q>>s) Eq 16

where the operator (x>>y) represent a y bits right shift of message x. For both examples s has been chosen equal to 2, that corresponds to a=1.333.

One may define a uniform quantization scheme (N_{b},p), where N_{b} is the number of bits (including sign) and p is the fraction of bits dedicated to the decimal part (i.e., the quantization interval is 2^{-p}). The adopted quantization schemes are the best for a given number of bits N_{b}. For the rate ⅔ code not even 8 bits are sufficient to perform close to the floating point precision. However, if the same quantization scheme is applied to decode a similar rate ⅔ code with size 648 bits, it results that L-N-MS with (8-4) performs better than floating point SPA at 12 iterations.

This result is consistent with the results reported in Zarkeshvari et al. (already cited), where it has been noted that the MS approximation works pretty well with short codes and quantized messages. For the higher rate code even 6 bits were found to lead to negligible losses.

The N-MS approach allows a significant reduction of the memory to store the check-to-bit messages Rᵢⱼ. In fact, the amount of memory turns out to be: (i) 2*nc*(N_{b}−1) bits for the modulus of the two least reliable check-to-bit messages of each check (where nc is the number of checks); (ii) the sign of all check-to-bit messages that result in E bits; (iii) the position of the least reliable message in the check that results in nc*ceil(log2(dc)) bits, where dc is (maximum) check-node degree, and [ceil] denotes the ceiling operator.

Table 2 below summarizes the results of comparison of the memory requirements for the approaches presented so far. Specifically, Table 2 refers to the memory needed to store the messages Rᵢⱼ and Qᵢⱼ and reports the results of comparison between conventional check-node and memory efficient MS approximation applied to different decoding algorithms.

| Algo. | Memory [bits] |
|---|---|
| SPA | 2 * E * N_{b} |
| MS | E * N_{b} + 2 * nc * (N_{b} − 1) + E + ceil (log2(dc)) |
| M-SPA | (E + 2 * n) * N_{b} |
| M-MS | 2 * n * N_{b} + 2 * nc * (N_{b} − 1) + E + ceil (log2(dc)) |
| L-SPA | (E + n) * N_{b} |
| L-MS | n * N_{b} + 2 * nc * (N_{b} − 1) + E + ceil (log2(dc)) |

The results in terms of memory requirements for the simulated codes indicate that the L-N-MS approach proposed herein requires 70% and 76% less memory than the conventional implementations of the SPA algorithm for rate ⅔ code and rate 0.9149 code, respectively. At the cost of some minor performance losses, memory requirements can be reduced by a factor 24%, 42% and 50% when the memory efficient MS solution is applied to SPA, M-SPA, and L-SPA, respectively, for the rate ⅔ code considered. For the rate 0.9149 code, the reduction amounts to 24%, 51% and 61%.

A “memory efficient” MS entails some significant, potential advantages that relate to the implementation of high-speed parallel decoders.

A first advantage lies in that a check-node requires much less input/output bits, so that routing problems can be scaled-down compared to a conventional approach. Secondly, in vectorized decoders explicitly dedicated to structured LDPCC (see, Novichkov et al. and WO-A-02/103631—both already cited), memory paging is designed so that all messages belonging to the same non-null sub-block in the parity check matrix are stored in the same memory word. A switch-bar is then adopted to cyclically rotate the message after/before the R/W operation. The approach discussed herein provides for the possibility of implementing switch-bars for A only.

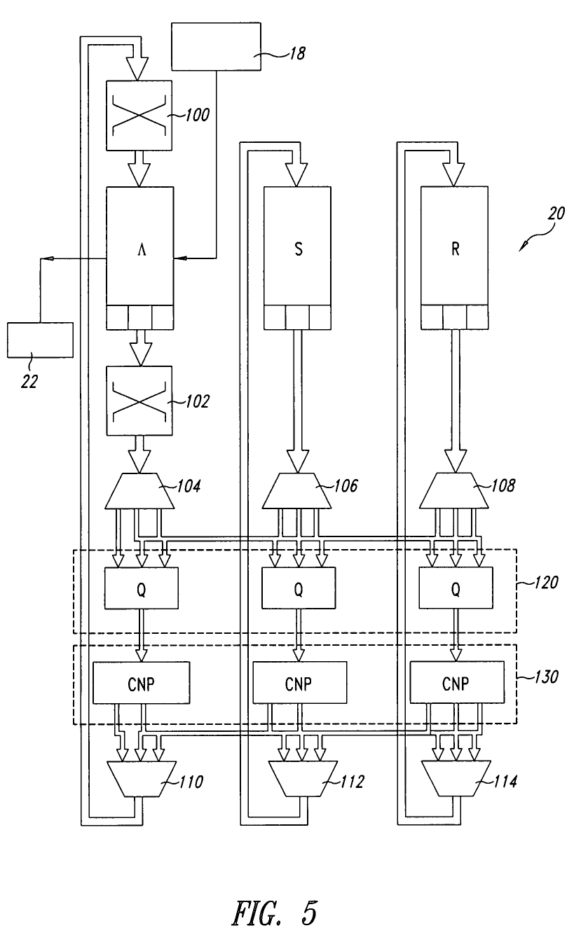

FIG. 5 is a functional block diagram of an embodiment of a decoder.

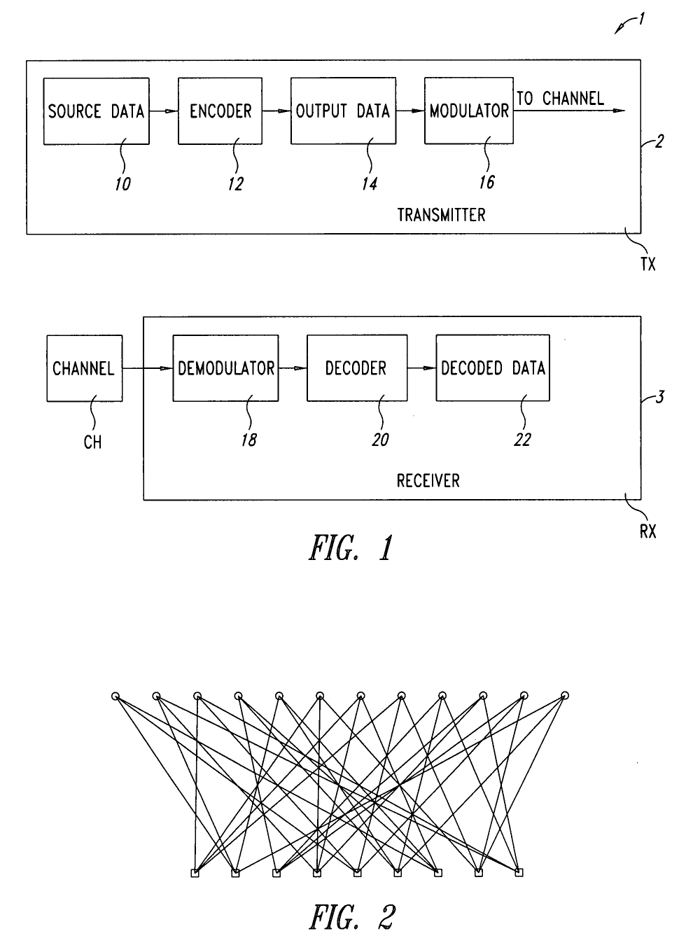

With reference to the general layout of FIG. 1, the decoder 20 is intended to be located downstream of the demodulator 18 to produce decoded data 22. The decoder 20 receives as its input the LLR values produced by the demodulator 18 (the demodulator may be implemented in a way to provide these values directly). The decoder 20 processes these LLR to retrieve the decoded data 22.

Referring to FIG. 5, the decoder 20 is configured to receive from the demodulator 18 initial values) λⱼ for initialization (i.e., Λⱼ=λⱼ for each j) and to produce as an output from a memory block designated A the messages Λⱼ which are representative of the a-posteriori probability of the output decoded data. Specifically, the decoder receives as its input the logarithm of the ratio of the likelihood for each bit, i.e., λⱼ; the decoder yields Λⱼ, i.e., the logarithm of the ratio of the a-posteriori probabilities.

The decoder 20 herein is assumed (just by way of example, with no intended limitation of the scope of the invention) to operate with “parallelism 3”, i.e., a structured LDPCC with subblock size equal to 3 is assumed. The basic layout of the arrangement implemented in the decoder of FIG. 5 is repeated below for immediate reference.

Λⱼ = λⱼ ∀ j
for k = 1:Nᵢₜₑ

for i = 1:nc

for j ∈ V(i)

if j ≠ M(i)

${\tilde{Q}}_{ji} = {Λ}_{j} - {R}_{i}^{1} {S}_{ji}$

else

${\tilde{Q}}_{ji} = {Λ}_{j} - {R}_{i}^{2} {S}_{ij}$

${R}_{i}^{1} = min \vert {\tilde{Q}}_{ji} \vert / α$
$M ( i ) = {arg}_{j} min \vert {\tilde{Q}}_{ji} \vert$
${R}_{i}^{2} = {min}_{j \neq M ( i )} \vert {\tilde{Q}}_{ji} \vert / α$
for j ∈ V(i)

${S}_{ij} = ( sign ( {\tilde{Q}}_{ji} ) \cdot {\prod }_{m ∈ V ( i )} sign ( {\tilde{Q}}_{mi} ) )$
if j ≠ M(i)

${Λ}_{j} = {\tilde{Q}}_{ji} + {R}_{i}^{1} {S}_{ij}$

else

${Λ}_{j} = {\tilde{Q}}_{ji} + {R}_{i}^{2} {S}_{ij}$

where Rᵢ¹ and Rᵢ² are the smallest and second smallest check-to-bit message modulus, M(i) is the least reliable bit in equation i, Sₘᵢ are the signs of the outgoing messages and α is the scaling factor of N-MS.

The memory block designated A stores the messages Λⱼ; each word contains the values belonging to three consecutive bit nodes.

The memory block designated S stores the signs Sᵢⱼ; three signs belonging to three consecutive messages └S_{3i,3j} S_{3i+1,3j+1} S_{3i+2,3j+2}┘ are arranged together to form a memory word.

The memory block designated R contains three messages related to the minimum and second minimum and minimum position, i.e., the memory block designated R contains three messages related to i) the value of the minimum, ii) the value of the second minimum and iii) the minimum position.

The messages are arranged together in such a way that all the messages related to the check equations that must be run in parallel (a super-code) can be read simultaneously; an example of memory word content is given below:

$$\begin{matrix}[ \begin{matrix}[ \begin{matrix}{R}_{3 i}^{1} & {R}_{3 i}^{2} & {M}_{3 i}\end{matrix} ] \\ [ \begin{matrix}{R}_{3 i + 1}^{1} & {R}_{3 i + 1}^{2} & {M}_{3 i + 1}\end{matrix} ] \\ [ \begin{matrix}{R}_{3 i + 2}^{1} & {R}_{3 i + 2}^{2} & {M}_{3 i + 2}\end{matrix} ]\end{matrix} ] & Eq 17\end{matrix}$$

The input messages to the memory block A and the output messages therefrom are rotated back and forward according to the proper shift values.

In the embodiment shown herein, this function is performed via switch-bars 100, 102 arranged at the input and the output of the memory block A.

The messages coming out of the memory blocks A, S, and R are demultiplexed towards the proper blocks Q configured to perform the computation of the values \tilde{Q}ⱼᵢ In the embodiment shown herein, the demultiplexing is performed via three demultiplexers 104, 106, and 108 each serving a respective one of three blocks Q. As illustrated, a bit-to-check module 120 comprises a plurality of bit-to-check generators Q.

The three blocks Q in turn feed a corresponding block CNP (Check Node Processor). The CNP blocks are configured to perform the following functions:
i) the search of the minimum, its position and the second minimum (Rᵢ¹; Rᵢ². Mᵢ);
ii) the computation of output signs Sᵢⱼ; and
iii) the computation of the new a-posteriori probabilities Λⱼ.

The output messages from the CNP blocks are then multiplexed via multiplexer blocks 110, 112, and 114 to be written back at the proper addresses in the memory blocks A, S, and R. As illustrated, a check node module 130 comprises a plurality of check node processors CNP.

The present invention is not limited to the embodiments described above. For instance, the foregoing detailed description has set forth various embodiments of the devices and/or processes via the use of block diagrams, schematics, and examples. Insofar as such block diagrams, schematics, and examples contain one or more functions and/or operations, it will be understood by those skilled in the art that each function and/or operation within such block diagrams, flowcharts, or examples can be implemented, individually and/or collectively, by a wide range of hardware, software, firmware, or virtually any combination thereof. In one embodiment, the present subject matter may be implemented via ASICs. However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof, and that designing the circuitry and/or writing the code for the software and or firmware would be well within the skill of one of ordinary skill in the art in light of this disclosure.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A method of decoding Low Density Parity Check (LDPC) encoded signals propagated over a channel by iteratively producing messages representative of an a-posteriori probability of output decoded signals as a function of check-to-bit messages produced from bit-to-check messages via check-node update computation, wherein said check-node update computation is performed as a MIN-SUM approximation and a reliability of output messages from the check-node update computation is determined by one of a least or second least reliable incoming message, the method comprising:
generating bit-to-check messages for parity check from a last version of the messages representative of the a-posteriori probability and past check-to-bit messages;
identifying a smallest modulus and a second smallest modulus of the bit-to-check messages, signs of the output messages and a position of the least reliable incoming message; and
producing an updated version of the messages representative of the a-posteriori probability of output decoded signals as a function of the smallest or the second smallest of the past check-to-bit messages, the signs of the output messages and the position of the least reliable incoming message.

2. The method of claim 1, including the step of multiplying the output messages from said check-node update by a scaling factor to compensate for effects of the MIN-SUM approximation applied in the computation of said reliability.

3. The method of claim 1, including the step of running in parallel a plurality of check-node update computations and the step of arranging in parallel to be read simultaneously all the messages related to said plurality of check-node update computations run in parallel.

4. The method of claim 1, including the step of implementing said check-node update computations as a search of:
a first and a second minimum for said smallest and the second smallest of said bit-to-check messages, respectively; and
the position of said first minimum as the position of said least reliable incoming message.

5. A decoder for decoding Low Density Parity Check (LDPC) encoded signals propagated over a channel, wherein said decoding produces messages representative of an a-posteriori probability of output decoded signals as a function of check-to-bit messages produced from bit-to-check messages via check-node update computation, the decoder including:
circuitry configured to perform said check-node update computation as a MIN-SUM approximation wherein a reliability of output messages from said check-node update computation is determined by one of a least or second least reliable of the incoming bit-to-check messages;
check node processor circuitry configured to identify a smallest and a second smallest modulus of said check-to-bit messages, the signs of said output messages and the position of said least reliable incoming message M(i), and producing said messages representative of the a-posteriori probability of output decoded signals as a function of said smallest and the second smallest modulus of said check-to-bit messages, signs of said output messages and the position of said least reliable incoming message.

6. The decoder of claim 5, further comprising:
circuitry configured to multiple the output messages from said check-node update by a scaling factor α compensate for effects of MIN-SUM approximation applied in the computation of said reliability.

7. The decoder of claim 5, further comprising:
circuitry configured to run in parallel a plurality of check-node update computations and arranged in parallel to read simultaneously all messages related to said plurality of check-node update computations run in parallel.

8. The decoder of claim 5 wherein said check node circuitry includes at least one check-node processor for performing said update computations as a search of:
a first and a second minimum for said smallest and the second smallest of said bit-to-check messages, respectively; and
the position M(i) of said first minimum as the position of said least reliable incoming message.

9. A decoder for decoding Low Density Parity Check (LDPC) encoded signals propagated over a channel, wherein said decoding produces messages representative of an a-posteriori probability of output decoded signals as a function of check-to-bit messages produced from bit-to-check messages via check-node update computation, the decoder including:
circuitry configured to perform said check-node update computation as a MIN-SUM approximation wherein a reliability of the output messages from said check-node update computation is determined by a least and second least reliable incoming message;
memory circuitry configured for storing a smallest and a second smallest modulus of said check-to-bit messages, signs of said output messages and a position of said least reliable incoming message, to produce therefrom an updated version of said messages representative of the a-posteriori probability of output decoded signals.

10. The decoder of claim 9 wherein the memory includes at least one modulus memory block for storing said smallest and second smallest modulus of said check-to-bit messages as well as said position of said least reliable incoming message.

11. The decoder of claim 9 wherein the memory includes an a-posteriori probability memory block for storing said messages representative of the a-posteriori probability, said a-posteriori probability memory block arranged in word locations, each word location adapted for containing values of a plurality of bit nodes.

12. The decoder of claim 11, including at least one shifter element to rotate by shift values the input messages to said a-posteriori probability memory block and the output messages therefrom.

13. The decoder of claim 11, wherein said at least one shifter element includes a switch-bar.

14. The decoder of claim 9 wherein the memory includes a sign memory block for storing said signs of said check-to-bit messages, said sign memory block arranged in word locations, each word location adapted for containing a plurality of signs belonging to plural messages arranged together to form a memory word.

15. The decoder of claim 9 wherein:
the memory includes
an a-posteriori probability memory block for storing said messages representative of a-posteriori probability; and
a sign memory block for storing said signs of said check-to-bit messages, wherein the circuitry configured to perform said check node update computation is configured to produce said messages representative of the a-posteriori probability of output decoded signals as a function of said smallest modulus and the second smallest modulus of said check-to-bit messages, the signs of said check-to-bit messages and the position of said least reliable incoming message; and
the decoder further comprises demultiplexer circuitry configured to demultiplex outputs from said memory circuitry as inputs to the circuitry configured to perform the check node update computation.

16. The decoder of claim 15, wherein said circuitry configured to perform the check node update computation includes at least one check-node processor fed for performing said update computations as a search of:
a first and a second minimum for said smallest and the second smallest of said check-to-bit messages, respectively; and
a position of said first minimum as the position of said least reliable incoming message.

17. The decoder of claim 16, further including multiplexer circuitry configured to multiplex outputs from the at least one check-node processor towards said memory circuitry.

18. A method of decoding Low Density Parity Check (LDPC) encoded signals propagated over a channel by producing messages representative of the a-posteriori probability of output decoded signals, the method including the joint adoption of minimum sum (MIN-SUM) approximation and layered decoding.

19. The method of claim 18 wherein the MIN-SUM approximation is normalized.

20. A computer program product for decoding Low Density Parity Check (LDPC) encoded signals propagated over a channel by producing messages representative of the a-posteriori probability of output decoded signals, the product loadable in the memory of at least one computer and including software code portions for performing the steps of:
iteratively producing messages representative of an a-posteriori probability of output decoded signals as a function of check-to-bit messages produced from bit-to-check messages via check-node update computation, wherein said check-node update computation is performed as a minimum-sum approximation and a reliability of output messages from said check-node update computation is determined by one of a least or second least reliable incoming message;
generating bit-to-check messages for parity check from a last version of the messages representative of the a-posteriori probability and past check-to-bit messages;
identifying a smallest modulus and a second smallest modulus of said bit-to-check messages, signs of said output messages and a position of said least reliable incoming message; and
producing an updated version of said messages representative of the a-posteriori probability of output decoded signals as a function of one of said smallest or the second smallest of modulus, the signs of said output messages and the position of said least reliable incoming message.

21. The computer program product of claim 20 wherein the minimum-sum approximation is normalized.

22. A decoder for decoding low-density-parity-check encoded signals, the decoder comprising:
a probability memory block for storing a set of check-to-bit messages;
a bit-to-check module configured to generate a set of bit-to-check messages from the set of check-to-bit messages;
a check node module configured to output a smallest and a second smallest modulus of messages in the set of bit-to-check messages, an identifier of a position associated with the smallest modulus, and a revised set of check-to-bit messages;
a modulus memory block configured to store the smallest modulus, the identifier and the second smallest modulus; and
a signs memory block configured to store signs of the revised set of check-to-bit messages.

23. The decoder of claim 22, further comprising:
a plurality of demultiplexers coupled between the memory blocks and the bit-to-check module, wherein the bit-to-check module comprises a plurality of bit-to-check generators; and
a plurality of multiplexers coupled between the check node module and the memory blocks, wherein the check node module comprises a plurality of check node processors.

24. The decoder of claim 23, further comprising:
a first shifter coupled between a multiplexer in the plurality of multiplexers and an input to the probability memory block; and
a second shifter coupled between an output of the probability memory block and a demultiplexer in the plurality of demultiplexers.

25. A method of decoding low density parity check signals, comprising:
storing a set of check-to-bit messages, a smallest modulus, a position associated with the smallest modulus, a second smallest modulus, and a set of signs;
generating a set of bit-to-check messages based on the set of check-to-bit messages, the smallest modulus, the position associated with the smallest modulus, the second smallest modulus, and the set of signs; and
revising the set of check-to-bit messages based on the set of bit-to-check messages, the smallest modulus, the position associated with the smallest modulus, the second smallest modulus and the set of signs.

26. The method of claim 25 wherein the generating the set of bit-to-check messages comprises:
when the position associated with the smallest modulus corresponds to a position of a message in the set of check-to-bit messages, generating a message in the set of bit-to-check messages based on the second smallest modulus; and
when the position associated with the smallest modulus does not correspond to the position of the message in the set of check-to-bit messages, generating the message in the set of bit-to-check messages based on the smallest modulus.

27. The method of claim 25 wherein the revising the set of check-to-bit messages comprises applying a scaling factor.

28. The method of claim 25, further comprising:
revising the smallest modulus, the position associated with the smallest modulus, the second smallest modulus, and the set of signs.

29. A computer-readable memory medium containing instructions that cause a processor to perform a method of decoding low density parity check signals, the method comprising:
storing a set of check-to-bit messages, a smallest modulus, a position associated with the smallest modulus, a second smallest modulus, and a set of signs;
generating a set of bit-to-check messages based on the set of check-to-bit messages, the smallest modulus, the position associated with the smallest modulus, the second smallest modulus, and the set of signs; and
revising the set of check-to-bit messages based on the set of bit-to-check messages, the smallest modulus, the position associated with the smallest modulus, the second smallest modulus and the set of signs.

30. The computer-readable memory medium of claim 29 wherein the generating the set of bit-to-check messages comprises:
when the position associated with the smallest modulus corresponds to a position of a message in the set of check-to-bit messages, generating a message in the set of bit-to-check messages based on the second smallest modulus; and
when the position associated with the smallest modulus does not correspond to the position of the message in the set of check-to-bit messages, generating the message in the set of bit-to-check messages based on the smallest modulus.

31. The computer-readable memory medium of claim 29 wherein the revising the set of check-to-bit messages comprises applying a scaling factor.

32. The computer-readable memory medium of claim 29, wherein the method further comprises:
revising the smallest modulus, the position associated with the smallest modulus, the second smallest modulus, and the set of signs.
